(19) United States
(12) Patent Application Publication
(10) Pub. No.: US 2025/0070057 A1
(43) Pub. Date: Feb. 27, 2025

(54) SEMICONDUCTOR DEVICE

(71) Applicant: FUJI ELECTRIC CO., LTD., Kawasaki-shi (JP)

(72) Inventor: Hiroaki ICHIKAWA, Kawasaki-shi (JP)

(73) Assignee: FUJI ELECTRIC CO., LTD., Kawasaki-shi (JP)

(21) Appl. No.: 18/756,112

(22) Filed: Jun. 27, 2024

(30) Foreign Application Priority Data
Aug. 22, 2023 (JP) 2023-134642

(51) Int. Cl. H01L 23/62; H01L 23/00; H01L 23/057; H01L 23/31; H01L 23/36; H01L 23/538; H02M 7/539; H03K 17/08

(52) U.S. Cl. CPC H01L 23/62; H01L 23/057; H01L 23/36; H01L 23/5385; H01L 23/315; H01L 24/32; H01L 24/48; H01L 24/73; H01L 2224/32225; H01L 2224/48225; H01L 2224/73265; H02M 7/539; H03K 17/08

(57) ABSTRACT

A semiconductor device, having: a circuit board, including a wiring board and a semiconductor element disposed on a first surface of the wiring board; a case having a hollow portion housing the circuit board; and a first conductive terminal and a second conductive terminal attached to the case, each of the first conductive terminal and the second conductive terminal having an inner connection portion exposed to the hollow portion of the case. The inner connection portions have a first gap therebetween in the hollow portion of the case. The first conductive terminal and the second conductive terminal each have a discharge portion facing each other across a second gap narrower than the first gap. The discharge portion of the first conductive terminal and the discharge portion of the second conductive terminal protrude to a position away from other members.

### CROSS-REFERENCE TO RELATED APPLICATION

The present application claims priority pursuant to 35 U.S.C. § 119 from Japanese patent application number 2023-134642 filed on Aug. 22, 2023, the entire disclosure of which is hereby incorporated by reference herein.

### BACKGROUND OF THE INVENTION

### 1. Technical Field

The present invention relates to a semiconductor device.

### 2. Description of the Related Art

Among semiconductor devices used in power conversion devices such as inverter devices, there is a semiconductor device configured to prevent a voltage applied to a semiconductor element in the device from becoming an overvoltage by performing discharge to avoid the overvoltage applied to the semiconductor element due to a lightning strike or the like and the breakdown of the semiconductor element (see, for example, JP 2015-15389 A and JP H06-224367 A). In addition, there is a semiconductor device that reduces a surge voltage by suppressing the parasitic inductance of a positive electrode terminal and a negative electrode terminal and increasing the parasitic capacitance between the positive electrode terminal and the negative electrode terminal (see, for example, JP 2022-6780 A).

### SUMMARY OF THE INVENTION

In the semiconductor device that avoids the breakdown of the semiconductor element by performing discharge, a gap between terminals used for discharge varies among individual devices, and thus the voltage at which discharge occurs easily fluctuates. The semiconductor device that reduces a surge voltage with the parasitic inductance or parasitic capacitance may not be able to sufficiently suppress the influence of an increase in the applied voltage or the like.

The present invention has been made in view of such a point, and an object of the present invention is to more reliably prevent the breakdown of the semiconductor element in the semiconductor device due to the application of an overvoltage exceeding an assumption in device design.

A semiconductor device according to one aspect of the present invention includes: a circuit board including a wiring board and a semiconductor element disposed on a first surface of the wiring board; a case having a hollow portion housing the circuit board; and a first conductive terminal and a second conductive terminal attached to the case, each of the first conductive terminal and the second conductive terminal having an inner connection portion exposed toward the hollow portion of the case and an outer connection portion exposed in a direction different away from the hollow portion, in which the first conductive terminal and the second conductive terminal each have a discharge portion facing each other across a second gap narrower than a first gap between the inner connection portions in the hollow portion of the case, and the discharge portion of the first conductive terminal and the discharge portion of the second conductive terminal protrude to a position away from other members and face each other via a gas.

According to the present invention, it is possible to more reliably prevent the breakdown of a semiconductor element in a semiconductor device due to an overvoltage exceeding an assumption in device design when the overvoltage is applied.

### BRIEF DESCRIPTION OF THE DRAWINGS

FIG. 1 is a top view illustrating a configuration example of a semiconductor device according to an embodiment;

FIG. 2 is a cross-sectional view schematically illustrating a cross-sectional configuration of the semiconductor device in FIG. 1;

FIG. 3 is an enlarged top view of a discharge portion in the semiconductor device in FIG. 1;

FIG. 4 is a cross-sectional view taken along line A-A′ in FIG. 3;

FIG. 5 is an equivalent circuit diagram of the semiconductor device in FIG. 1;

FIG. 6 is a graph for explaining a setting method of a gap between the discharge portions;

FIG. 7 is a table for explaining a setting example of the gap between the discharge portions;

FIG. 8 is a perspective view (part 1) for explaining an example of a manufacturing method of a discharge wiring board;

FIG. 9 is a perspective view (part 2) for explaining the example of the manufacturing method of the discharge wiring board;

FIG. 10 is a perspective view (part 3) for explaining the example of the manufacturing method of the discharge wiring board;

FIG. 11 is an enlarged top view illustrating a modification of the discharge wiring board;

FIG. 12 is a cross-sectional view taken along line B-B′ in FIG. 11;

FIG. 13 is a perspective view for explaining another configuration example of the discharge portion;

FIG. 14 is a C-arrow view of the discharge portion in FIG. 13;

FIG. 15 is a top view illustrating another configuration example of the semiconductor device;

FIG. 16 is an equivalent circuit diagram for explaining an example of an inverter circuit using the semiconductor device illustrated in FIG. 15;

FIG. 17 is a cross-sectional view for explaining another example of a connection method of the discharge wiring board; and

FIGS. 18A and 18B are partial top views for explaining a modification of the shape of the discharge portion.

### DETAILED DESCRIPTION

Hereinafter, an embodiment of the present invention will be described in detail with reference to the drawings. Note that the X axis, the Y axis, and the Z axis in each of the drawings to be referred to are illustrated for the purpose of defining a plane and a direction in the exemplified semiconductor device or the like. The X, Y, and Z axes are orthogonal to each other and form a right-handed system. In the following description, a direction parallel to the X axis is referred to as an X direction, a direction parallel to the Y axis is referred to as a Y direction, and a direction parallel to the Z axis is referred to as a Z direction. In addition, in a case where each of the X direction, the Y direction, and the Z direction is associated with a direction of an arrow (positive or negative) of the X axis, the Y axis, and the Z axis illustrated, a “positive side” or a “negative side” is added.

In the present specification, the Z direction may be referred to as a vertical direction. In the present specification, “on” and “upper side” are intended to be on the positive side in the Z direction with respect to the reference surface, member, position, and the like, and “below” and “lower side” are intended to be on the negative side in the Z direction with respect to the reference surface, member, position, and the like. For example, when it is described that “the member B is disposed on the member A”, the member B is disposed on the positive side in the Z direction as viewed from the member A. Further, when the “upper surface of the member A” is described, the surface is positioned at the end of the member A on the positive side in the Z direction and faces the positive side in the Z direction. In the present specification, “top view” is intended as a plan view when a target article (for example, a semiconductor device or the like) is viewed from the positive side in the Z direction. In the present specification, the “side view” is intended as a plan view when a target article is viewed from the negative side in the X direction or the positive side in the X direction, and the plan view when viewed from the negative side in the X direction may be referred to as a “left side view”, and the plan view when viewed from the positive side in the X direction may be referred to as a “right side view”. Such directions and surfaces are terms used for convenience of description. Thus, depending on a posture of attachment of the semiconductor device, a correspondence relationship with directions of the X, Y, and Z axes may vary. For example, in the present specification, a surface of a semiconductor element facing a wiring board is referred to as a lower surface, and a surface opposite to the lower surface is referred to as an upper surface, but the terms are not limited thereto, and the surface facing the wiring board may be referred to as the upper surface, and the surface opposite thereto may be referred to as the lower surface. The lower surface and the upper surface of the semiconductor element may be referred to as side surfaces. Furthermore, an aspect ratio and a size relationship between the members in each drawing are merely schematically represented, and do not necessarily coincide with a relationship in a semiconductor device or the like actually manufactured. For convenience of description, it is also assumed that the size relationship between the members is exaggerated. In addition, for convenience of description, some of the cross-sectional views illustrate cross-sectional configurations of the semiconductor device cut along a virtual cutting line that cannot be accurately illustrated in the top view (plan view). Furthermore, some of the cross-sectional views schematically illustrate portions of the semiconductor device positioned at the back of the cross section.

The descriptions of “not illustrated” and the like in the present specification are intended not to clearly indicate which part in the figure a component to which the description is given is using a specific reference sign and a leader line. For example, a “first main electrode not illustrated” means that a portion representing the first main electrode (for example, a figure, a line, or the like) is not illustrated in the figure, and that there is neither a reference sign nor a leader line clearly indicating a portion corresponding to the first main electrode in the figure. In addition, the underlined reference signs in the drawings indicate the entire components including a plurality of portions distinguished from one another by a plurality of reference signs.

A semiconductor device to be illustrated in the following description may be applied to, for example, a power conversion device such as an industrial or electrical (for example, an in-vehicle motor's) inverter device. Thus, in the following description, detailed description of the same or similar configuration, function, operation, manufacturing method, and the like as those of the known semiconductor device will be omitted.

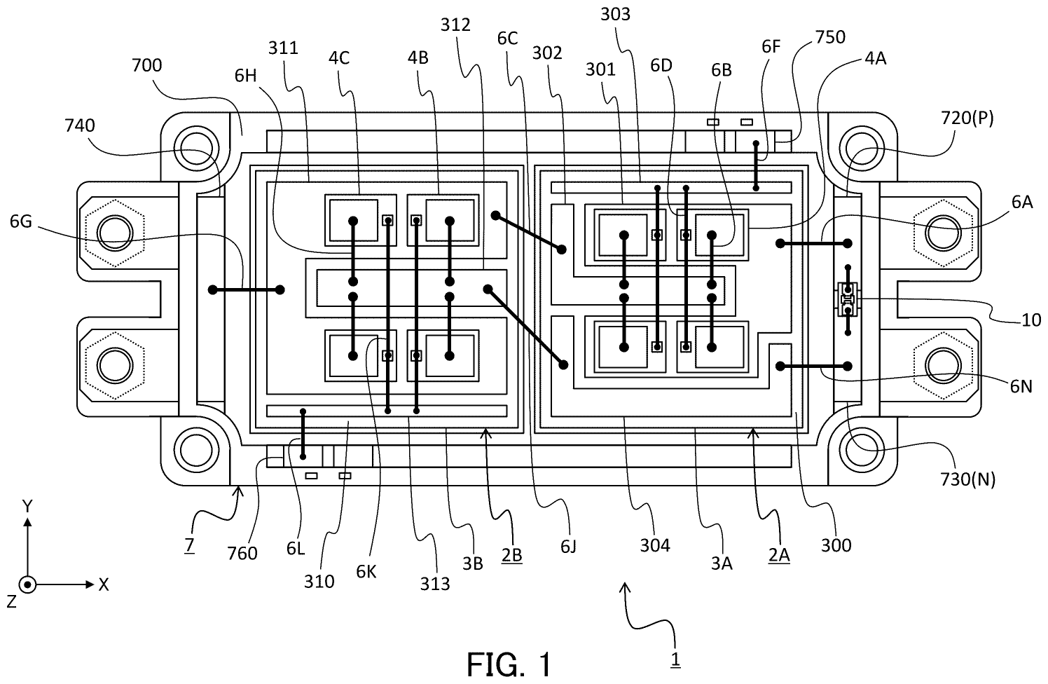

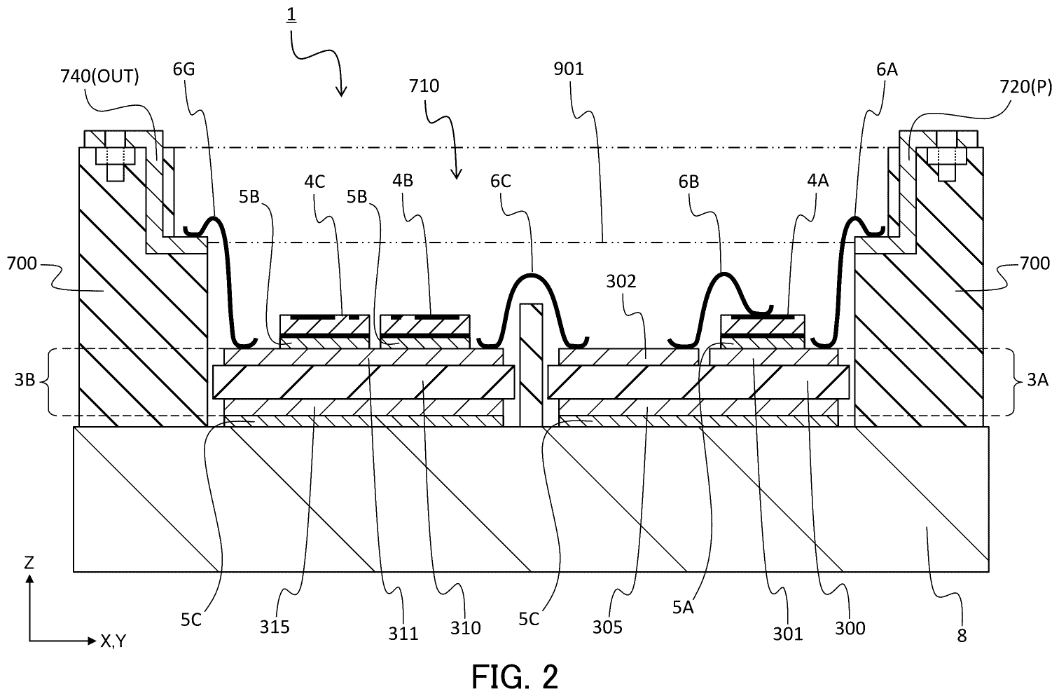

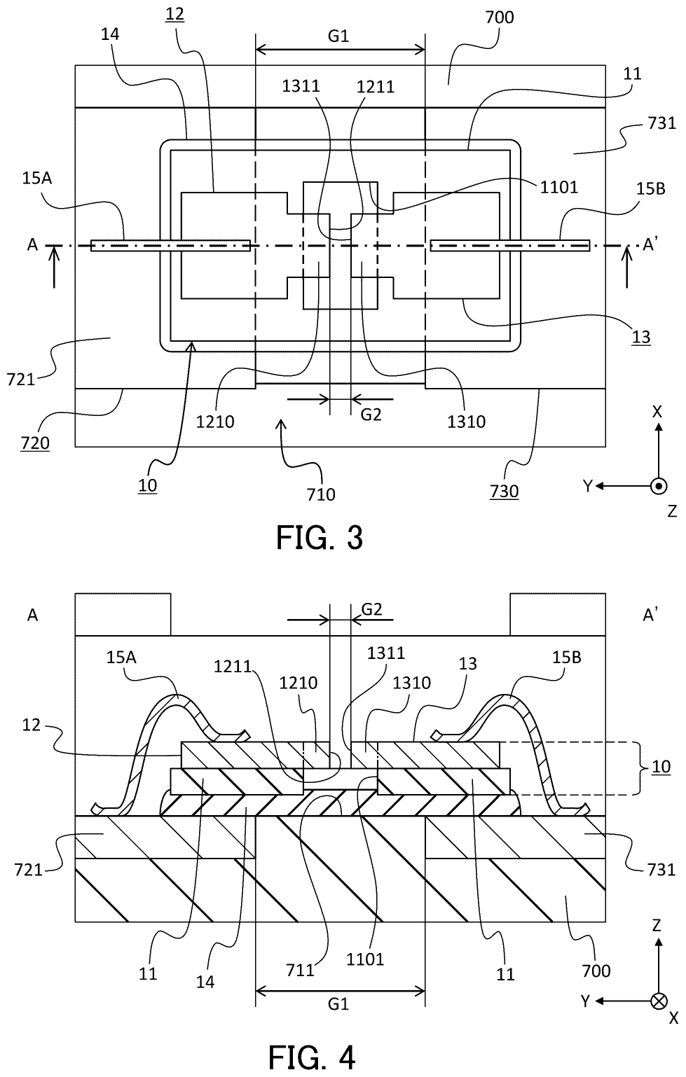

FIG. 1 is a top view illustrating a configuration example of a semiconductor device according to an embodiment. FIG. 2 is a cross-sectional view schematically illustrating a cross-sectional configuration of the semiconductor device in FIG. 1. FIG. 3 is an enlarged top view of a discharge portion in the semiconductor device in FIG. 1. FIG. 4 is a cross-sectional view taken along line A-A′ in FIG. 3. In each of FIGS. 1 to 4, a lid disposed on an upper surface of a case and a sealing material that seals a circuit board housed in the case are omitted. In addition, the cross-sectional view in FIG. 2 schematically illustrates a cross-sectional configuration associated with a current path between a first main terminal and a third main terminal in the semiconductor device illustrated in FIG. 1.

A semiconductor device 1 illustrated in FIGS. 1 and 2 includes a first circuit board 2A, a second circuit board 2B, a case 7, and a cooler 8.

The first circuit board 2A includes a first wiring board 3A and four semiconductor elements including a first semiconductor element 4A disposed on an upper surface of the first wiring board 3A. The first wiring board 3A includes an insulating substrate 300, conductor patterns 301 to 304 provided on an upper surface of the insulating substrate 300, and a conductor pattern 305 provided on a lower surface of the insulating substrate 300. The second circuit board 2B includes a second wiring board 3B and four semiconductor elements including a second semiconductor element 4B and a third semiconductor element 4C disposed on an upper surface of the second wiring board 3B. The second wiring board 3B includes an insulating substrate 310, conductor patterns 311 to 313 provided on an upper surface of the insulating substrate 310, and a conductor pattern 315 provided on a lower surface of the insulating substrate 310. In the following description, the plurality of semiconductor elements will be referred to as “semiconductor elements 4” when not distinguished from one another.

The first wiring board 3A and the second wiring board 3B can be, for example, a direct copper bonding (DCB) substrate or an active metal brazing (AMB) substrate. The first wiring board 3A and the second wiring board 3B may be referred to as a laminated substrate, an insulating circuit board, or the like.

The insulating substrates 300 and 310 are not limited to a specific substrate. The insulating substrates 300 and 310 may be, for example, a ceramic substrate made of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrates 300 and 310 may be, for example, a substrate obtained by molding an insulating resin such as epoxy resin, a substrate obtained by impregnating a base material such as a glass fiber with an insulating resin, a substrate obtained by coating a surface of a flat plate-shaped metal core with an insulating resin, or the like.

The conductor patterns 301 to 304 provided on the upper surface of the insulating substrate 300 and the conductor patterns 311 to 313 provided on the upper surface of the insulating substrate 310 function as wiring of an inverter circuit to be described later. These conductor patterns 301 to 304 and 311 to 313 are formed of, for example, metal plates, metal foils, or the like such as copper or aluminum. These conductor patterns 301 to 304 and 311 to 313 may be referred to as conductor layers, conductor plates, conductive layers, wiring patterns, or the like.

Each of the plurality of semiconductor elements 4 disposed on the upper surface of the first wiring board 3A and the upper surface of the second wiring board 3B includes, for example, a reverse conducting (RC)-insulated gate bipolar transistor (IGBT) element in which an IGBT element that is a switching element and a function of a diode element such as a free wheeling diode (FWD) element connected in anti-parallel to the IGBT element are integrated. In this type of semiconductor elements 4, a first main electrode (not illustrated) is provided on the lower surface, and a second main electrode and a control electrode (gate electrode) (not illustrated) are provided on the upper surface. When the switching elements of the semiconductor elements 4 are IGBT elements, the first main electrode on the lower surface side may be referred to as a collector electrode, and the second main electrode on the upper surface side may be referred to as an emitter electrode. In addition, the semiconductor substrate on which the switching element and the diode element in the semiconductor elements 4 are formed is not limited to a silicon substrate, and may be, for example, a substrate using a wide band gap semiconductor such as a silicon carbide (SiC) substrate or a gallium nitride (GaN) substrate.

The four semiconductor elements 4 (including the first semiconductor element 4A) included in the first circuit board 2A are disposed on the first conductor pattern 301 in the first wiring board 3A, and first main electrodes (collector electrodes) are bonded to the first conductor pattern 301 by bonding materials 5A. The bonding material 5A may be, for example, a well-known solder. The first conductor pattern 301 is electrically connected to a first main terminal (P terminal) 720 provided on the case 7 by a bonding wire 6A. Second main electrodes (emitter electrodes) of the semiconductor elements 4 included in the first circuit board 2A are electrically connected to the second conductor pattern 302 of the first wiring board 3A by bonding wires. For example, the second main electrode (not illustrated) of the first semiconductor element 4A is electrically connected to the second conductor pattern 302 by a bonding wire 6B. The second conductor pattern 302 is electrically connected to the first conductor pattern 311 of the second wiring board 3B by a bonding wire 6C. In addition, control electrodes (gate electrodes) of the semiconductor elements 4 included in the first circuit board 2A are electrically connected to the third conductor pattern 303 of the first wiring board 3A by bonding wires. For example, the control electrode of the first semiconductor element 4A is electrically connected to the third conductor pattern 303 by a bonding wire 6D. The third conductor pattern 303 of the first wiring board 3A is electrically connected to a control terminal 750 provided on the case 7 by a bonding wire 6F.

The four semiconductor elements 4 (including the second semiconductor element 4B and the third semiconductor element 4C) included in the second circuit board 2B are disposed on the first conductor pattern 311 in the second wiring board 3B, and first main electrodes (collector electrodes) are bonded to the first conductor pattern 311 by bonding materials 5B. The bonding material 5B may be, for example, a well-known solder. The first conductor pattern 311 is electrically connected to a third main terminal (OUT terminal) 740 provided on the case 7 by a bonding wire 6G. Second main electrodes (emitter electrodes) of the semiconductor elements 4 included in the second circuit board 2B is electrically connected to the second conductor pattern 312 of the second wiring board 3B by a bonding wire. For example, the second main electrode (not illustrated) of the third semiconductor element 4C is electrically connected to the second conductor pattern 312 by a bonding wire 6H. The second conductor pattern 312 is electrically connected to the fourth conductor pattern 304 of the first wiring board 3A by a bonding wire 6J. The fourth conductor pattern 304 of the first wiring board 3A is electrically connected to the second main terminal (N terminal) 730 provided on the case 7 by a bonding wire 6N. In addition, control electrodes (gate electrodes) of the semiconductor elements 4 included in the second circuit board 2B are electrically connected to the third conductor pattern 313 of the second wiring board 3B by bonding wires. For example, the control electrode of the third semiconductor element 4C is electrically connected to the third conductor pattern 313 via the control electrode of another semiconductor element 4 by a bonding wire 6K. The third conductor pattern 313 of the second wiring board 3B is electrically connected to a control terminal 760 provided on the case 7 by a bonding wire 6L.

The first circuit board 2A and the second circuit board 2B in the semiconductor device 1 described above may be replaced with a single circuit board.

The number of bonding wires that electrically connect two conductors is not limited to one, and may be plural. For example, the bonding wire 6A that connects the first main terminal 720 of the case 7 and the first conductor pattern 301 of the first wiring board 3A may be a set of a plurality of bonding wires. In addition, for example, the bonding wire 6B that connects the second main electrode of the first semiconductor element 4A and the second conductor pattern 302 of the first wiring board 3A may be a set of a plurality of bonding wires. In addition, the two conductors may be electrically connected by a conductor not limited to the bonding wire, for example, a conductive member formed by bending a conductor plate such as a copper plate, which may be referred to as a lead, a lead frame, or the like.

The conductor pattern 305 provided on the lower surface of the insulating substrate 300 in the first wiring board 3A functions as a heat conducting member that conducts heat generated by the semiconductor elements 4 disposed on the first wiring board 3A to the cooler 8. Similarly, the conductor pattern 315 provided on the lower surface of the insulating substrate 310 in the second wiring board 3B functions as a heat conducting member that conducts heat generated by the semiconductor elements 4 disposed on the second wiring board 3B to the cooler 8. These conductor patterns 305 and 315 are formed of, for example, a metal plate or a metal foil such as copper or aluminum. The first circuit board 2A is fixed on the cooler 8 by bonding the conductor pattern 305 of the first wiring board 3A to an upper surface of the cooler 8 with a bonding material 5C such as solder. The second circuit board 2B is fixed on the cooler 8 by bonding the conductor pattern 315 of the second wiring board 3B to the upper surface of the cooler 8 with the bonding material 5C such as solder. The cooler 8 includes, for example, a flow path of refrigerant in which a plurality of fins are disposed, and performs heat exchange between the fins whose temperature has increased by heat from the plurality of semiconductor elements 4 and the refrigerant flowing through the flow path. The cooler 8 may be any component in the semiconductor device 1 according to the present embodiment. The semiconductor device 1 according to the present embodiment may be, for example, a device in which the first circuit board 2A and the second circuit board 2B are disposed on an upper surface of a heat radiation base different from the cooler 8, and in which the heat radiation base is thermally connected to the cooler 8 separate from the semiconductor device 1. In this type of semiconductor device 1, the heat radiation base and the cooler 8 may be brought into close contact with each other by, for example, a thermal conductive material such as a thermal grease or a thermal compound. The cooler 8 may be, for example, a member called a heat sink or the like that releases heat to surrounding gas.

The case 7 includes a case member 700 having a housing portion 710 capable of housing the first circuit board 2A and the second circuit board 2B disposed on the upper surface of the cooler 8 (or the heat radiation base), the bonding wires 6A to 6N, and the like, and the above-described first main terminal (P terminal) 720, second main terminal (N terminal) 730, third main terminal (OUT terminal) 740, and control terminals 750 and 760.

The case member 700 of the case 7 illustrated in FIGS. 1 and 2 has a substantially annular shape in a top view having a hollow portion with an upper end and a lower end open, and the hollow portion is used as the housing portion 710 that houses the first circuit board 2A, the second circuit board 2B, and the like. Each of the above-described first main terminal 720, second main terminal 730, third main terminal 740, and control terminals 750 and 760 includes an inner connection portion exposed inside the housing portion 710 of the case member 700 and an outer connection portion exposed from an upper surface of the case member 700, and is provided integrally with the case member 700. This type of case 7 is manufactured by a known manufacturing method such as a method using insert molding. The case member 700 is formed, for example, using an insulating resin material such as poly phenylene sulfide (PPS) or polyamide (PA). The first main terminal 720, the second main terminal 730, the third main terminal 740, and the control terminals 750 and 760 are formed by, for example, processing a conductive plate such as a copper plate. The first main terminal 720, the second main terminal 730, and the third main terminal 740 may be referred to as bus bars or the like. Each of the first main terminal 720, the second main terminal 730, and the third main terminal 740 is bent such that the outer connection portion is along the upper surface of the case member 700. The outer connection portion of each main terminal covers a nut (not illustrated) housed in a recessed portion formed on the upper surface of the case member 700, and a through-hole is formed at a position corresponding to a screw hole of the nut. To the outer connection portion of each main terminal of the semiconductor device 1, for example, a conductor plate that may be referred to as a bus bar, a terminal of a power cable, or the like is connected by screwing a bolt (not illustrated) into the nut housed in the case member 700.

In the case 7, for example, the case member 700 is adhered to the upper surface of the cooler 8 (or the heat radiation base) with an adhesive. The housing portion 710 of the case 7 is filled with a scaling material (not illustrated) that seals the first circuit board 2A, the second circuit board 2B, and the like. The sealing material may be an epoxy resin, silicone gel, or the like, for example. The sealing material may be a combination of two or more types of insulating materials. For example, as illustrated in FIG. 2, the sealing material is filled such that a connection portion between the inner connection portion and the bonding wire on the main terminal of the case 7 is positioned above an upper surface 901 of the scaling material. In addition, for example, an opening on the upper end side of the housing portion 710 of the case 7 may be covered with a lid.

As illustrated in FIGS. 3 and 4, in the case 7 in the semiconductor device 1 according to the present embodiment, an inner connection portion 721 of the first main terminal 720 and an inner connection portion 731 of the second main terminal 730 are disposed across a gap G1 on a single surface 711 of the case member 700 facing the housing portion 710. A discharge wiring board 10 is disposed above the surface 711 on which the inner connection portion 721 of the first main terminal 720 and the inner connection portion 731 of the second main terminal 730 are disposed.

The discharge wiring board 10 illustrated in FIGS. 3 and 4 includes an insulating substrate 11, and a first conductor pattern 12 and a second conductor pattern 13 disposed on an upper surface of the insulating substrate 11. The insulating substrate 11 of the discharge wiring board 10 can be, for example, a film-shaped substrate such as a polyimide film used for a well-known flexible printed wiring board. On the insulating substrate 11, an opening 1101 with an upper surface and a lower surface open is formed.

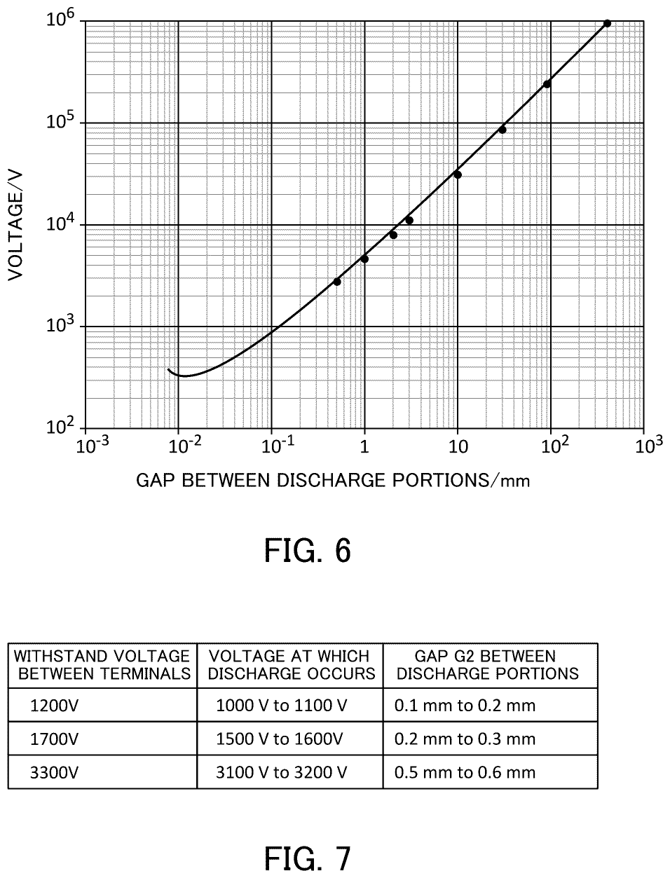

The first conductor pattern 12 and the second conductor pattern 13 of the discharge wiring board 10 are, for example, obtained by patterning a conductive layer such as a copper foil or a copper plating layer, and have a discharge portion (i.e., discharge end) 1210 and a discharge portion (i.e., discharge end) 1310, respectively, extending (protruding) over the opening 1101 of the insulating substrate 11. The discharge portion 1210 refers to a portion of the first conductor pattern 12 that is positioned on the opening 1101 and has a lower surface not in contact with the insulating substrate 11, and the discharge portion 1310 refers to a portion of the second conductor pattern 13 that is positioned on the opening 1101 and has a lower surface not in contact with the insulating substrate 11. The discharge portion 1210 of the first conductor pattern 12 and the discharge portion 1310 of the second conductor pattern 13 face each other across a gap G2 on the opening 1101 of the insulating substrate 11. The discharge portion 1210 of the first conductor pattern 12 and the discharge portion 1310 of the second conductor pattern 13 are formed such that end surfaces 1211 and 1311 facing the other discharge portion are entirely positioned on the opening 1101 of the insulating substrate 11. The end surfaces 1211 and 1311 may be referred to as discharge surfaces. The gap G2 between the end surface 1211 of the first conductor pattern 12 and the end surface 1311 of the second conductor pattern 13 is smaller than the gap G1 between the inner connection portion 721 of the first main terminal 720 and the inner connection portion 731 of the second main terminal 730 (for example, several mm to several tens of mm). A specific example of the size of the gap G2 will be described later with reference to FIGS. 6 and 7.

FIGS. 3 and 4 schematically illustrate an example of the shapes of the discharge portions 1210 and 1310. The shapes of the discharge portions 1210 and 1310 are not limited to the rectangular parallelepiped illustrated in FIGS. 3 and 4. In FIGS. 3 and 4, the end surfaces (discharge surfaces) 1211 and 1311 of the discharge portions 1210 and 1310, respectively, are described to be flat such that other surfaces (for example, an upper surface, a lower surface, and the like) are in contact with an outer periphery (each side) of the end surface at a right angle. However, in the case of such a shape in which there are corners on the outer peripheries of the end surfaces 1211 and 1311 of the facing discharge portions, for example, an electric field may concentrate at the corner portions and the discharge start voltage may drop, and thus a problem that the discharge start voltage cannot be controlled unless the shapes of the corner portions can be controlled may occur. Therefore, as illustrated in FIGS. 18A and 18B, the shapes of the discharge portions 1210 and 1310 may be such a shape as to suppress the concentration of an electric field at the outer peripheries of the end surfaces (discharge surfaces) 1211 and 1311 of the discharge portions 1210 and 1310, respectively, or prevent the concentration of the electric field from occurring. FIGS. 18A and 18B are partial top views for explaining a modification of the shape of the discharge portion.

As a first modification of the shape of the discharge portion, FIG. 18A illustrates an example of a shape in which the other surfaces are in contact with the outer periphery (side) of the end surface (discharge surface) of the discharge portion at an obtuse angle. The end surface 1211 of the discharge portion 1210 of the first conductor pattern 12 illustrated in FIG. 18A has a rectangular planar shape, and a first inclined surface 1212 and a second inclined surface 1213 are in contact with an end side on the positive side in the X direction and an end side on the negative side in the X direction of the end surface 1211, respectively, at an obtuse angle. Similarly, the end surface 1311 of the discharge portion 1310 of the second conductor pattern 13 illustrated in FIG. 18A has a rectangular planar shape, and a first inclined surface 1312 and a second inclined surface 1313 are in contact with an end side on the positive side in the X direction and an end side on the negative side in the X direction of the end surface 1311, respectively, at an obtuse angle. By forming the discharge portions 1210 and 1310 in such a shape, it is possible to suppress the concentration of an electric field at the end portions on the positive side in the X direction and the negative side in the X direction, or prevent the concentration of the electric field from occurring. In addition, the shapes of the discharge portions 1210 and 1310 illustrated in FIG. 18A may be, for example, a shape in which inclined surfaces are in contact with each of an end side on the positive side in the Z direction and an end side on the negative side in the Z direction of the end surfaces 1211 and 1311 at an obtuse angle. The angle between the end surface (discharge surface) of the discharge portion and the other surfaces in contact with the outer periphery (side) of the end surface is not limited to a specific angle.

As a second modification of the shape of the discharge portion, FIG. 18B illustrates an example of a shape in which the outer periphery of the end surface (discharge surface) of the discharge portion is a convex curved surface. In the discharge portion 1210 of the first conductor pattern 12 illustrated in FIG. 18B, the end portion on the positive side in the X direction and the end portion on the negative side in the X direction on the end surface 1211 are a first convex curved surface 1216 and a second convex curved surface 1217, respectively. Similarly, in the discharge portion 1310 of the second conductor pattern 13 illustrated in FIG. 18B, the end portion on the positive side in the X direction and the end portion on the negative side in the X direction on the end surface 1311 are a first convex curved surface 1316 and a second convex curved surface 1317, respectively. By forming the discharge portion 1210 and 1310 in such a shape, it is possible to prevent the concentration of an electric field from occurring at the end portions on the positive side in the X direction and the negative side in the X direction. In addition, the shapes of the discharge portions 1210 and 1310 illustrated in FIG. 18B may be, for example, a shape in which each of an end portion on the positive side in the Z direction and an end portion on the negative side in the Z direction of the end surfaces 1211 and 1311 is also a convex curved surface. The curvature of the convex curved surface on the end surface (discharge surface) of the discharge portion is not limited to a specific curvature. For example, the end surfaces (discharge surfaces) 1211 and 1311 of the discharge portions 1210 and 1310 may have a convex spherical shape as indicated by two-dot chain lines in FIG. 18B.

The discharge wiring board 10 is adhered onto the surface 711 of the case member 700 with an adhesive 14. The first conductor pattern 12 of the discharge wiring board 10 is electrically connected to the inner connection portion 721 of the first main terminal 720 by a bonding wire 15A, and functions as a discharge portion of the first main terminal 720. The second conductor pattern 13 of the discharge wiring board 10 is electrically connected to the inner connection portion 731 of the second main terminal 730 by a bonding wire 15B, and functions as a discharge portion of the second main terminal 730.

In the discharge wiring board 10 illustrated in FIGS. 3 and 4, the discharge portion 1210 of the first conductor pattern 12 and the discharge portion 1310 of the second conductor pattern 13 extend (protrude) over the opening 1101 formed on the insulating substrate 11. That is, the discharge portion 1210 of the first conductor pattern 12 and the discharge portion 1310 of the second conductor pattern 13 protrude to a position away from other members such as the adhesive 14 and the insulating substrate 11 on the surface 711 of the case member 700, and face each other. Thus, since the distance between the end surface 1211 of the first conductor pattern 12 and the end surface 1311 of the second conductor pattern 13 facing each other is short, the discharge start voltage in the air between the end surfaces is lower than the discharge start voltage of creeping discharge along the surface of another member (for example, an insulating member such as the insulating substrate 11), thus preventing the creeping discharge from occurring. An area around the discharge portions 1210 and 1310 may be filled with air or may be filled with a gas different from air (for example, nitrogen gas or the like).

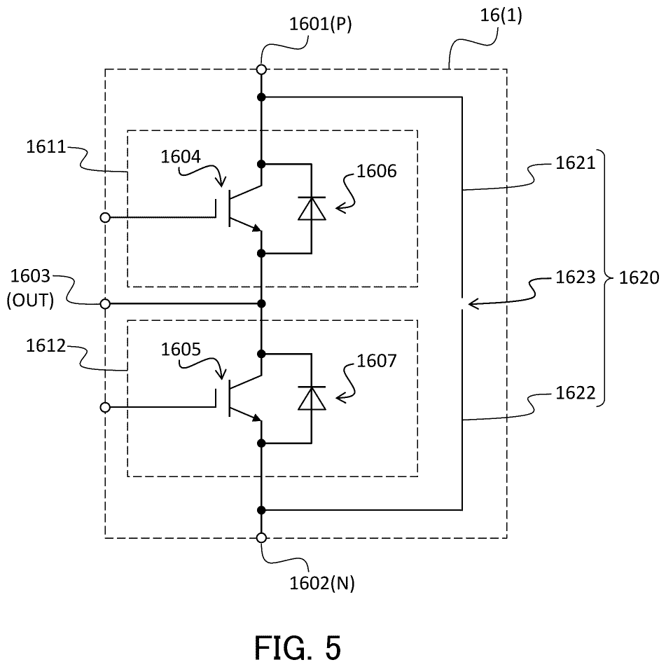

FIG. 5 is an equivalent circuit diagram of the semiconductor device in FIG. 1. FIG. 5 illustrates a half-bridge inverter circuit 16 as an example of an equivalent circuit of the semiconductor device 1.

In the half-bridge inverter circuit 16, for example, a first switching element 1604 and a second switching element 1605 are connected in series between a P terminal 1601 connected to a positive electrode of an external DC power supply and an N terminal 1602 connected to a negative electrode. The P terminal 1601 and the N terminal 1602 can be the first main terminal 720 and the second main terminal 730, respectively, of the semiconductor device 1 illustrated in FIG. 1. The first switching element 1604 is a switching element included in the semiconductor element of the first circuit board 2A in the semiconductor device 1 illustrated in FIG. 1, and has a collector connected to the P terminal 1601. The second switching element 1605 is a switching element included in the semiconductor element of the second circuit board 2B in the semiconductor device 1 illustrated in FIG. 1, and has an emitter connected to the N terminal 1602. The emitter of the first switching element 1604 is connected to the collector of the second switching element 1605 and an OUT terminal 1603.

A first diode element 1606 included in the semiconductor element of the first circuit board 2A is connected in anti-parallel to the first switching element 1604, and a second diode element 1607 included in the semiconductor element of the second circuit board 2B is connected in anti-parallel to the second switching element 1605. The diode elements 1606 and 1607 may be FWDs. A set 1611 of the first switching element 1604 and the first diode element 1606 connected between the P terminal 1601 and the OUT terminal 1603 may be referred to as an upper arm 1611, and a set 1612 of the second switching element 1605 and the second diode element 1607 connected between the N terminal 1602 and the OUT terminal 1603 may be referred to as a lower arm 1612.

The half-bridge inverter circuit 16 illustrated in FIG. 5 includes a discharge path 1620 including a first branch wiring 1621 branched from a wiring connecting the P terminal 1601 and the collector of the first switching element 1604 and a second branch wiring 1622 branched from a wiring connecting the N terminal 1602 and the emitter of the second switching element 1605. In the discharge path 1620, the first branch wiring 1621 and the second branch wiring 1622 are electrically separated from each other by a gap 1623. The first branch wiring 1621 corresponds to, for example, the first conductor pattern 12 and the bonding wire 15A of the discharge wiring board 10 described above with reference to FIGS. 3 and 4. The second branch wiring 1622 corresponds to, for example, the second conductor pattern 13 and the bonding wire 15B of the discharge wiring board 10 described above with reference to FIGS. 3 and 4.

Under an environment in which a semiconductor device having the half-bridge inverter circuit 16 illustrated in FIG. 5 is used, for example, an excessive increase in commercial power supply voltage or the like exceeding the assumption of device design due to a lightning strike or the like may occur. When the commercial power supply voltage increases, the voltage applied to the first switching element 1604 and the second switching element 1605 exceeds the maximum rated voltage range (in other words, the voltage applied to the switching elements becomes an overvoltage exceeding the allowable range), and thus there is a risk that the switching element breaks down. In the half-bridge inverter circuit 16 illustrated in FIG. 5, the discharge path 1620 is provided to prevent the breakdown of the semiconductor element (switching element) due to the overvoltage. The discharge path 1620 can be a current path that performs discharge to prevent the breakdown (damage) of the semiconductor elements of the upper arm 1611 and the lower arm 1612 when a potential difference between the P terminal 1601 and the N terminal 1602 increases due to an overvoltage caused by a lightning strike or the like. The magnitude (potential difference) of the voltage at which discharge occurs in the discharge path 1620 can be controlled by the size of the gap 1623 between the first branch wiring 1621 and the second branch wiring 1622. In other words, the magnitude of the voltage at which discharge occurs can be controlled by the gap G2 (see FIGS. 3 and 4) between the discharge portion 1210 of the first conductor pattern 12 of the discharge wiring board 10 corresponding to the first branch wiring 1621 and the discharge portion 1310 of the second conductor pattern 13 of the discharge wiring board 10 corresponding to the second branch wiring 1622.

FIG. 6 is a graph for explaining a setting method of the gap between the discharge portions. FIG. 7 is a table for explaining a setting example of the gap between the discharge portions. The graph in FIG. 6 and the table in FIG. 7 are associated with the setting method and the setting example of the gap G2 when the shapes of the discharge portions 1210 and 1310 are such a shape as to prevent the concentration of an electric field from occurring (see, for example, FIGS. 18A and 18B).

In the graph illustrated in FIG. 6, the horizontal axis represents a gap between the discharge portions (unit: mm) indicated on a logarithmic scale, and the vertical axis represents the voltage at which discharge occurs (unit: V) indicated on a logarithmic scale. A thick curve in FIG. 6 indicates the relationship between the gap between the discharge portions and the voltage at which discharge occurs under the atmospheric pressure of 1013.25 hPa according to Paschen's law. “•” in FIG. 6 indicates the relationship between the gap between the discharge portions with a standard sphere (standard sphere gap) and the voltage at which a spark discharge occurs.

As can be seen from the graph illustrated in FIG. 6, when the gap between the discharge portions is 0.1 mm or more, the voltage at which discharge occurs increases as the gap increases. Meanwhile, in the semiconductor device 1 in FIG. 1 corresponding to the half-bridge inverter circuit 16 illustrated in FIG. 5, for example, the withstand voltage of the semiconductor elements 4 connected between the first main terminal (P terminal) 720 and the second main terminal (N terminal) 730 varies depending on intended uses. Therefore, to prevent the breakdown of the semiconductor elements 4 due to an overvoltage, it is preferable to reliably perform discharge at a stage where the voltage (potential difference) between the first main terminal 720 and the second main terminal 730 is smaller than the maximum rated voltage (withstand voltage) specified based on the circuit configuration between the terminals.

FIG. 7 illustrates a preferable relationship among the withstand voltage between the terminals to be protected, the voltage at which discharge occurs, and the gap G2 between the discharge portions, which are set based on the graph illustrated in FIG. 6. For example, when the withstand voltage between the first main terminal (P terminal) 720 and the second main terminal (N terminal) 730 is 1200 V, it is preferable to perform discharge at 1000 V to 1100 V to reliably prevent the breakdown of the semiconductor elements 4 due to an overvoltage. Therefore, the gap G2 between the discharge portion 1210 of the first conductor pattern 12 and the discharge portion 1310 of the second conductor pattern 13 on the discharge wiring board 10 used in the semiconductor device 1 having a withstand voltage of 1200 V is set to, for example, 0.1 mm to 0.2 mm in accordance with Paschen's law.

When the withstand voltage between the terminals is 1700 V, for example, the gap G2 between the discharge portion 1210 of the first conductor pattern 12 and the discharge portion 1310 of the second conductor pattern 13 on the discharge wiring board 10 is set to 0.2 mm to 0.3 mm to perform discharge at 1500 V to 1600 V, thereby making it possible to prevent the breakdown of the semiconductor elements 4 due to an overvoltage exceeding the withstand voltage. When the withstand voltage between the terminals is 3300 V, for example, the gap G2 between the discharge portion 1210 of the first conductor pattern 12 and the discharge portion 1310 of the second conductor pattern 13 on the discharge wiring board 10 is set to 0.5 mm to 0.6 mm to perform discharge at 3100 V to 3200 V, thereby making it possible to prevent the breakdown of the semiconductor elements 4 due to an overvoltage exceeding the withstand voltage.

Note that the graph in FIG. 6 and the table in FIG. 7 are associated with the setting method and the setting example of the gap G2 when the shapes of the discharge portions 1210 and 1310 are such a shape as to prevent the concentration of an electric field from occurring (see, for example, FIGS. 18A and 18B). When the shapes of the discharge portions 1210 and 1310 are a shape in which the concentration of an electric field can occur (for example, the rectangular parallelepiped as described above with reference to FIGS. 3 and 4), the size of the gap G2 is set in consideration of the drop in the discharge start voltage due to the concentration of the electric field. When the concentration of the electric field occurs, the gap G2 set based on a certain discharge start voltage (for example, 1000 V to 1100 V) is larger than the gap G2 set based on the discharge start voltage described with reference to the table in FIG. 7.

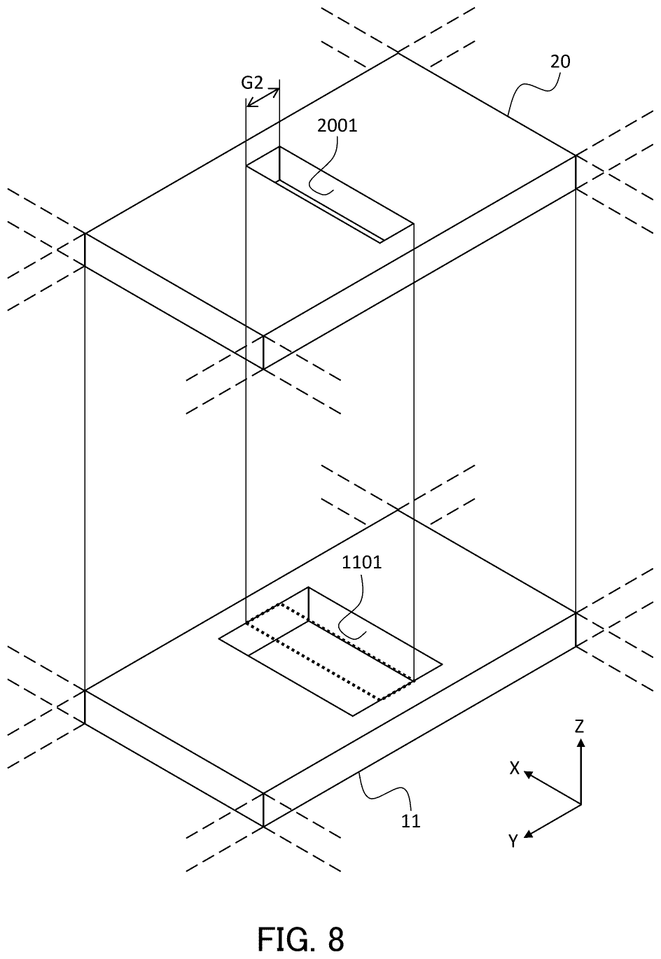

The manufacturing method of the above-described discharge wiring board 10 is not limited to a specific method. However, from the viewpoint of accurately controlling the gap G2 between the discharge portion 1210 of the first conductor pattern 12 and the discharge portion 1310 of the second conductor pattern 13 to reduce the variation among individual discharge wiring boards 10, for example, it is preferable to manufacture the discharge wiring board 10 by the method described below with reference to FIGS. 8 to 10.

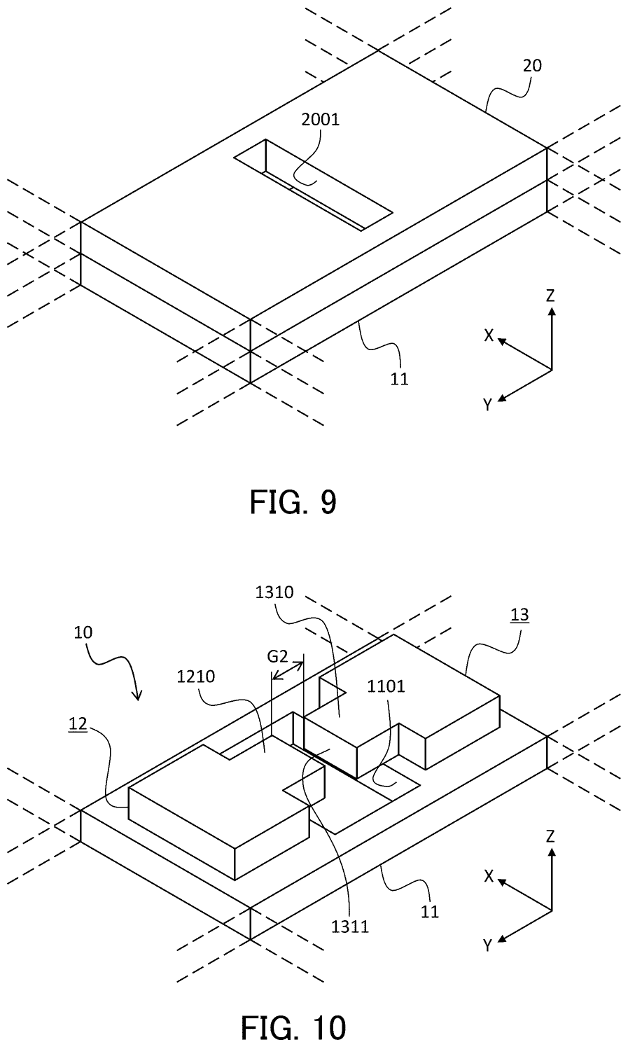

FIG. 8 is a perspective view (part 1) for explaining an example of the manufacturing method of the discharge wiring board. FIG. 9 is a perspective view (part 2) for explaining an example of the manufacturing method of the discharge wiring board. FIG. 10 is a perspective view (part 3) for explaining an example of the manufacturing method of the discharge wiring board. When the discharge wiring board is actually manufactured, one discharge wiring board indicated by the solid line in FIGS. 8 to 10 is manufactured in a state of being continuous in the X direction and the Y direction, and is divided into individual discharge wiring boards in the final process.

When the discharge wiring board 10 is manufactured, first, as illustrated in FIGS. 8 and 9, a laminate obtained by laminating a conductor film 20 having a slit 2001 and the insulating substrate 11 having the opening 1101 is formed. The conductor film 20 may be a metal foil such as a rolled copper foil or an electrolytic copper foil. The thickness of the conductor film 20 can be, for example, about 30 μm to 50 μm, but is not limited to a specific thickness. The slit 2001 of the conductor film 20 is formed with a width corresponding to the gap G2 between the discharge portion 1210 of the first conductor pattern 12 and the discharge portion 1310 of the second conductor pattern 13. The slit 2001 is formed by, for example, laser processing or the like. The insulating substrate 11 may be a film-shaped insulating substrate such as a polyimide film. The opening 1101 is formed by, for example, a punch die (blank die). The conductor film 20 and the insulating substrate 11 are laminated to each other with, for example, an adhesive (not illustrated). The opening 1101 of the insulating substrate 11 may be, for example, a bottomed recess formed by routing and having an open upper surface side to which the conductor film 20 is laminated.

Thereafter, as illustrated in FIG. 10, the conductor film 20 in the formed laminate is patterned to form the first conductor pattern 12 and the second conductor pattern 13. The patterning of the conductor film 20 is performed by etching. When the first conductor pattern 12 and the second conductor pattern 13 are formed by etching, it is possible to prevent the surfaces facing each other of the discharge portions 1210 and 1310 (the end surfaces 1211 and 1311 in FIG. 4) from being etched if an etching resist having a portion that passes over the slit 2001 and is continuous with a resist portion on the discharge portion 1210 of the first conductor pattern 12 and a resist portion on the discharge portion 1310 of the second conductor pattern 13 is formed as an etching resist. That is, by forming the first conductor pattern 12 and the second conductor pattern 13 by etching the conductor film 20 having the slit 2001, it is possible to reduce the variation in the gap G2 between the discharge portion 1210 of the first conductor pattern 12 and the discharge portion 1310 of the second conductor pattern 13 among a plurality of individual discharge wiring boards 10.

Therefore, by using the discharge wiring board 10 manufactured by the method described above with reference to FIGS. 8 to 10, it is possible to reduce the variation in the magnitude of the voltage at which discharge occurs (potential difference) among individual discharge wiring boards 10. In other words, the configuration of the discharge portion for preventing the breakdown (damage) of the semiconductor elements inside the semiconductor device 1 due to an overvoltage is less likely to vary among individual discharge wiring boards 10. For this reason, for example, even when an overvoltage exceeding an assumption in device design is applied to the semiconductor device 1, the breakdown of the semiconductor elements 4 can be stably prevented, and thus a failure, an emergency stop, or the like of the power conversion device using the semiconductor device 1 can be avoided. In addition, since the variation in the magnitude of the voltage at which discharge occurs (discharge start voltage) among individual discharge wiring boards 10 can be reduced, the discharge portion can be configured to perform discharge at a voltage lower than the withstand voltage of the semiconductor elements 4 between the terminals and closer to the withstand voltage, and thus the withstand voltage of the semiconductor elements 4 can be sufficiently utilized.

Furthermore, by forming the shapes of the discharge portions 1210 and 1310 formed by etching such that the other surfaces are not in contact with the outer peripheries (sides) of the end surfaces 1211 and 1311 at a right angle as illustrated in FIGS. 18A and 18B, it is possible to reduce the variation in the magnitude of the discharge start voltage among individual discharge wiring boards 10 due to the above-described concentration of an electric field, and thus to take advantage of the withstand voltage of the semiconductor elements 4.

On the other hand, in the semiconductor device in JP 2015-15389A described above, discharge is performed between the discharge planar electrode provided on the matching substrate and the discharge needle electrode attached to the metal cap that is the ceiling portion of the case. However, in such a semiconductor device, the gap between the discharge planar electrode and the discharge needle electrode is likely to vary among individual devices. For this reason, for example, the gap between the discharge planar electrode and the discharge needle electrode is increased so that the voltage (potential difference) causing discharge in the actually manufactured semiconductor device does not exceed the withstand voltage of the semiconductor element, and thus the withstand voltage of the semiconductor element may not be sufficiently utilized.

In addition, in the semiconductor device described above in JP H06-224367 A, a high-resistance film (insulator) is interposed in the gap between the first metal film and the second metal film that perform discharge. In such a semiconductor device, for example, the size and composition of the high-resistance film in the gap between the first metal film and the second metal film are likely to vary among individual devices. In addition, in the semiconductor device described in JP H06-224367 A, for example, there is a possibility that the high-resistance film interposed in the gap between the first metal film and the second metal film burns out during discharge, causing the breakdown of the semiconductor element.

Furthermore, in the semiconductor device in JP 2022-6780A described above, for example, the relative arrangement relationship between the positive electrode terminal and the negative electrode terminal is likely to vary among individual devices, and the parasitic capacitance between the positive electrode terminal and the negative electrode terminal is likely to vary among individual devices. For this reason, in the semiconductor device that reduces a surge voltage with the parasitic capacitance, for example, the influence of an increase in the applied voltage (for example, commercial power supply voltage) due to a lightning strike or the like may not be able to be sufficiently suppressed, and thus the semiconductor element may break down.

In the semiconductor device 1 according to the present embodiment, by using the above-described discharge wiring board 10, it is possible to easily reduce a variation in the voltage at which discharge occurs (discharge start voltage) among individual devices as compared with the semiconductor devices of JP 2015-15389 A, JP H06-224367 A, and JP 2022-6780 A, and thus it is possible to more reliably prevent the breakdown of the semiconductor elements 4 due to an overvoltage. For this reason, the power conversion device including the semiconductor device according to the present embodiment can avoid, for example, an excessive increase in the commercial power supply voltage exceeding an assumption of device design due to a lightning strike or the like, and a failure, an emergency stop, or the like of the device due to electro-static discharge (ESD). In addition, in the discharge wiring board 10, the discharge portion 1210 of the first conductor pattern 12 and the discharge portion 1310 of the second conductor pattern 13 extend over the opening 1101 of the insulating substrate 11, and face each other in a state of protruding to a position away from other members such as the insulating substrate 11, the case member 700, and the adhesive 14. For this reason, it is possible to prevent the insulating member in the vicinity from burning out due to creeping discharge along the surface of the discharge wiring board 10, and to prevent the damage to the semiconductor device 1. The discharge portions are only required to face each other in a gas, separated from a solid material such as the case member 700 and the adhesive 14. The discharge portions may face each other not only in air, but also in a gas such as an inert gas (for example, nitrogen gas) filled in a space scaled by the case member 700 and the lid (not illustrated). In addition, the air pressure in the space sealed by the case member 700 and the lid (not illustrated) may be different from the atmospheric pressure. As described above, the discharge portions may have a shape in which the other surfaces are in contact with the outer periphery (side) of the end surface at an obtuse angle, or a shape in which the outer periphery or the entire area of the end surface is a convex curved surface.

The discharge wiring board 10 used in the semiconductor device 1 according to the present embodiment is not limited to the configuration described above with reference to FIGS. 3 and 4.

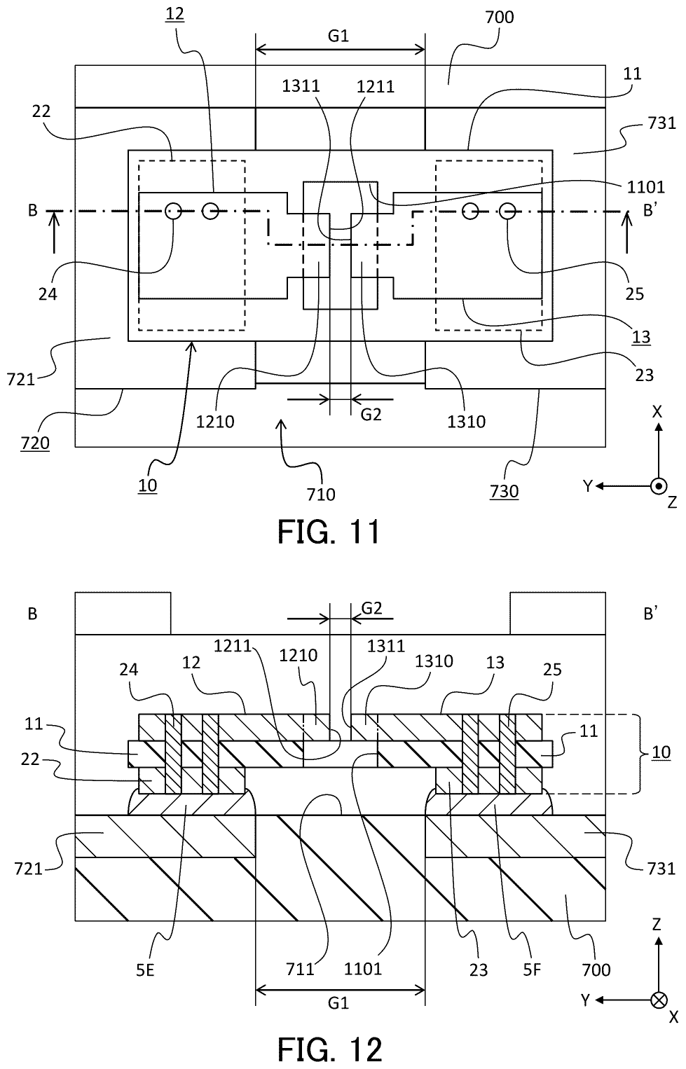

FIG. 11 is an enlarged top view illustrating a modification of the discharge wiring board. FIG. 12 is a cross-sectional view taken along line B-B′ in FIG. 11.

In the discharge wiring board 10 illustrated in FIGS. 11 and 12, the first conductor pattern 12 and the second conductor pattern 13 are formed on the upper surface of the insulating substrate 11. The opening 1101 is formed on the insulating substrate 11, and the discharge portion 1210 of the first conductor pattern 12 and the discharge portion 1310 of the second conductor pattern 13 extend (protrude) over the opening 1101 and face each other across the gap G2.

In the discharge wiring board 10 illustrated in FIGS. 11 and 12, a third conductor pattern 22 electrically connected to the first conductor pattern 12 and a fourth conductor pattern 23 electrically connected to the second conductor pattern 13 are formed on the lower surface of the insulating substrate 11. The first conductor pattern 12 and the third conductor pattern 22 are electrically connected by through-hole plating 24 formed in a through-hole penetrating the first conductor pattern 12, the insulating substrate 11, and the third conductor pattern 22. The second conductor pattern 13 and the fourth conductor pattern 23 are electrically connected by through-hole plating 25 formed in a through-hole penetrating the second conductor pattern 13, the insulating substrate 11, and the fourth conductor pattern 23. In the discharge wiring board 10 in which the conductor patterns are formed on the upper surface and the lower surface of the insulating substrate 11, the third conductor pattern 22 is bonded to the inner connection portion 721 of the first main terminal 720 of the case 7 by a bonding material 5E, and the fourth conductor pattern 23 is bonded to the inner connection portion 731 of the second main terminal 730 of the case 7 by a bonding material 5F.

The discharge wiring board 10 illustrated in FIGS. 11 and 12 can be formed by etching. For example, in the step described above with reference to FIGS. 8 and 9 of laminating the conductor film 20 having the slit 2001 on the upper surface of the insulating substrate 11 having the opening 1101, or before or after the same step, another conductive film is also laminated onto the lower surface of the insulating substrate 11 to form a double-sided copper-clad laminate. Thereafter, the through-holes penetrating the conductor film 20 on the upper surface of the insulating substrate 11, the insulating substrate 11, and the conductive film on the lower surface of the insulating substrate 11 are formed, and the through-hole plating 24 and 25 are formed in the through-holes. After the through-hole plating 24 and 25 are formed, the conductor film 20 on the upper surface and the conductive film on the lower surface of the insulating substrate 11 are patterned by etching, whereby the first conductor pattern 12 and the second conductor pattern 13, and the third conductor pattern 22 and the fourth conductor pattern 23 can be formed.

Also in the discharge wiring board 10 described above with reference to FIGS. 11 and 12, the shapes of the discharge portion 1210 of the first conductor pattern 12 and the discharge portion 1310 of the second conductor pattern 13 are not limited to the rectangular parallelepiped illustrated in FIGS. 11 and 12. The shapes of the discharge portions 1210 and 1310 may be, for example, a shape in which the other surfaces are in contact with the outer peripheries (sides) of the end surfaces 1211 and 1311 at an obtuse angle, or a shape in which the outer periphery or the entire area of the end surface is a convex curved surface as illustrated in FIGS. 18A and 18B. By forming a shape such that the other surfaces are not in contact with the outer peripheries (sides) of the end surfaces 1211 and 1311 at a right angle, it is possible to suppress the above-described concentration of an electric field at the outer peripheral portions of the end surfaces 1211 and 1311 or prevent the concentration of the electric field from occurring.

The discharge portion 1210 of the first conductor pattern 12 and the discharge portion 1310 of the second conductor pattern 13 of the discharge wiring board 10 illustrated in FIGS. 11 and 12 are electrically connected to the first main terminal 720 and the second main terminal 730 of the case 7 via the bonding materials 5E and 5F, respectively, such as solder positioned below the discharge wiring board 10. Thus, for example, it is possible to prevent interference between the bonding wire 6A (see FIGS. 1 and 2) that connects the first main terminal 720 and the first conductor pattern 301 of the first wiring board 3A and the bonding wire 15A that connects the first conductor pattern 12 of the discharge wiring board 10 and the first main terminal 720.

The method for electrically connecting the conductor pattern provided on the upper surface of the insulating substrate 11 and the conductor pattern provided on the lower surface is not limited to the above-described method using the through-hole plating 24 and 25, and other methods may be used. For example, electrical connection is performed by a via formed by filling a via hole penetrating the conductor film 20 on the upper surface or the conductor film on the lower surface of the insulating substrate 11 and the insulating substrate 11 with a conductor by plating or the like.

Furthermore, in the semiconductor device 1 according to the present embodiment, instead of using the discharge wiring board 10, for example, a discharge portion may be formed in each of the first main terminal 720 and the second main terminal 730.

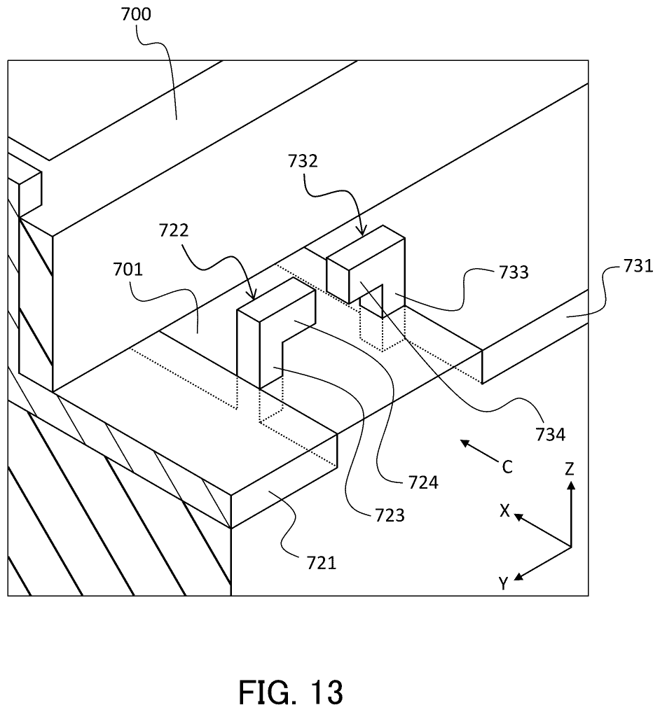

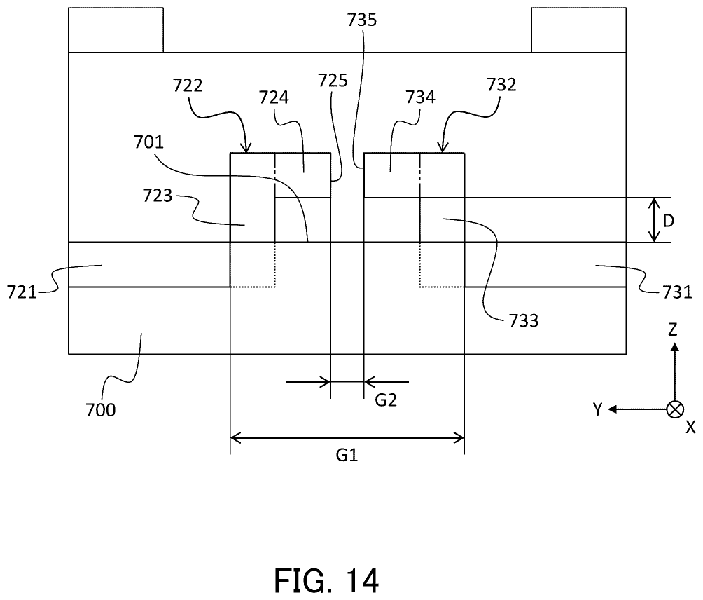

FIG. 13 is a perspective view for explaining another configuration example of the discharge portion. FIG. 14 is a C-arrow view of the discharge portion in FIG. 13.

The semiconductor device 1 illustrated in FIGS. 13 and 14 includes a first discharge portion 722 protruding from the inner connection portion 721 of the first main terminal 720 and a second discharge portion 732 protruding from the inner connection portion 731 of the second main terminal 730.

The first discharge portion 722 includes a first portion 723 extending upward from the surface 711 of the case member 700 on which the first main terminal 720 is disposed, and a second portion 724 extending from an upper end portion of the first portion 723 along the surface 711 in a direction approaching the second main terminal 730. The second portion 724 extends in a direction along the surface 711 at a position away from the surface 711 of the case member 700 by a distance D. The second discharge portion 732 includes a first portion 733 extending upward from the surface 711 of the case member 700 on which the second main terminal 730 is disposed, and a second portion 734 extending from an upper end portion of the first portion 733 along the surface 711 in a direction approaching the first main terminal 720. The second portion 734 extends in a direction along the surface 711 at the position away from the surface 711 of the case member 700 by the distance D. The second portion 724 of the first discharge portion 722 and the second portion 734 of the second discharge portion 732 face each other across the gap G2. The second portion 724 of the first discharge portion 722 and the second portion 734 of the second discharge portion 732 illustrated in FIGS. 13 and 14 correspond to the discharge portion 1210 of the first conductor pattern 12 and the discharge portion 1310 of the second conductor pattern 13 on the discharge wiring board 10 described above with reference to FIGS. 3 and 4.

In the semiconductor device 1 including the first discharge portion 722 and the second discharge portion 732 described above with reference to FIGS. 13 and 14, as in the semiconductor device 1 including the discharge wiring board 10, it is possible to reduce the variation in the gap G2 between the second portions 724 and 734 among individual devices, and to prevent the insulator such as the case member 700 from burning out during discharge.

A forming method of the case 7 including the first main terminal 720 having the first discharge portion 722 and the second main terminal 730 having the second discharge portion 732 is not limited to a specific method. For example, after the case 7 is formed by insert molding using the first main terminal 720 and the second main terminal 730 in which the second portion 724 of the first discharge portion 722 and the second portion 734 of the second discharge portion 732 are integrated, the second portion 724 of the first discharge portion 722 and the second portion 734 of the second discharge portion 732 can be cut to form the gap G2 by laser machining or electric discharge machining. The shapes of the second portion 724 of the first discharge portion 722 and the second portion 734 of the second discharge portion 732 are not limited to the rectangular parallelepiped illustrated in FIGS. 13 and 14. The shapes of the second portion 724 of the first discharge portion 722 and the second portion 734 of the second discharge portion 732 can also be similar to the shapes of the discharge portions 1210 and 1310 illustrated in FIGS. 18A and 18B. By forming a shape such that the other surfaces are not in contact with the outer peripheries (sides) of the end surface (discharge surface) 725 of the second portion 724 of the first discharge portion 722 and the end surface 735 of the second portion 734 of the second discharge portion 732 at a right angle, it is possible to suppress the above-described concentration of an electric field at the outer peripheral portions of the end surfaces 725 and 735 or prevent the concentration of the electric field from occurring.

In addition, the semiconductor device provided with the above-described discharge portion is not limited to the semiconductor device 1 (see FIG. 1) in which the half-bridge inverter circuit 16 described above with reference to FIG. 5 is formed.

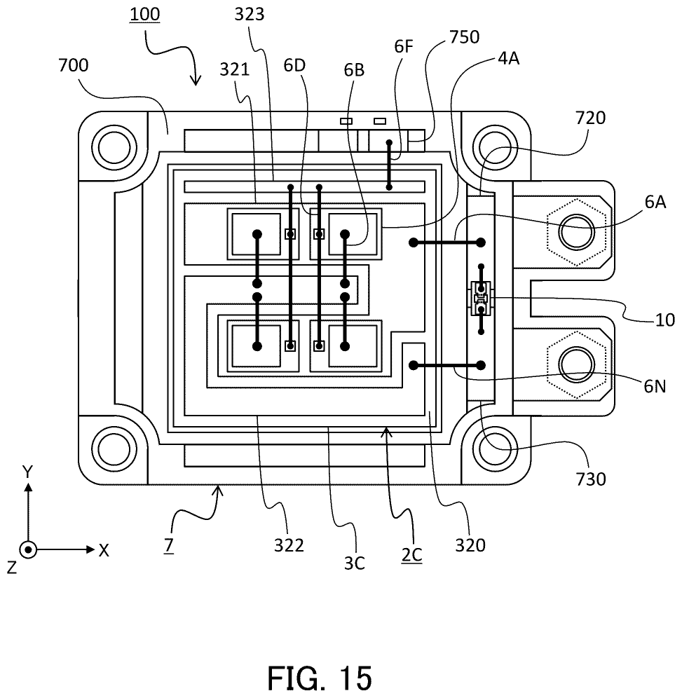

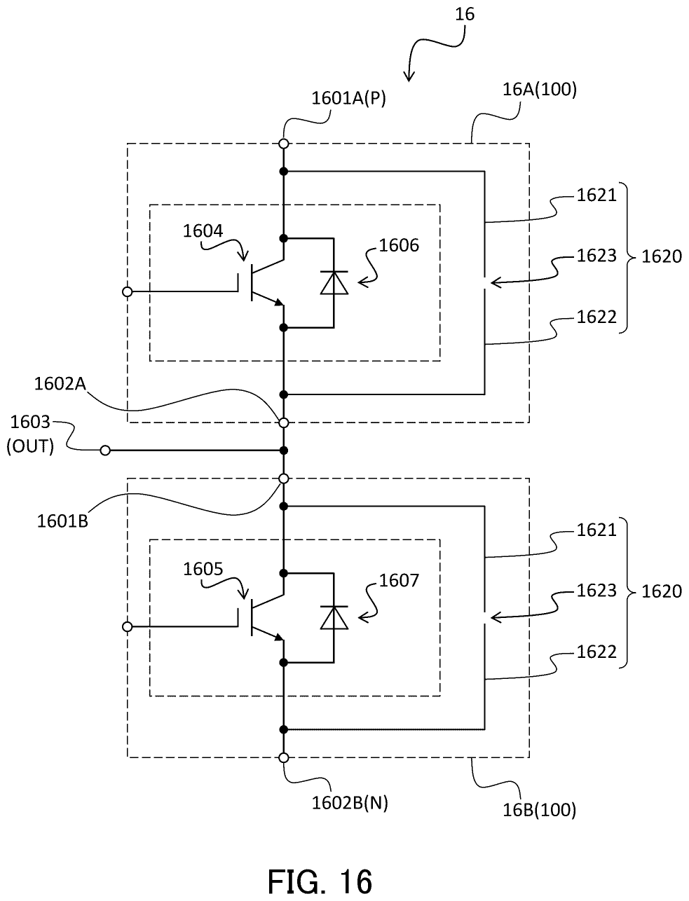

FIG. 15 is a top view illustrating another configuration example of the semiconductor device. FIG. 16 is an equivalent circuit diagram for explaining an example of an inverter circuit using the semiconductor device illustrated in FIG. 15.

A semiconductor device 100 illustrated in FIG. 15 is provided with the first main terminal 720, the second main terminal 730, and the control terminal 750 in the case 7 that houses a circuit board 2C. In other words, in the case 7 of the semiconductor device 100, the third main terminal 740 and the control terminal 760 in the case 7 of the semiconductor device 1 described above with reference to FIG. 1 and the like are omitted. The circuit board 2C includes a wiring board 3C and four semiconductor elements (including the first semiconductor element 4A) disposed on an upper surface of the wiring board 3C. The wiring board 3C includes an insulating substrate 320, conductor patterns 321 to 323 provided on an upper surface of the insulating substrate 320, and a conductor pattern (not illustrated) provided on a lower surface of the insulating substrate 320. The four semiconductor elements on the circuit board 2C are, for example, the above-described RC-IGBT elements, and the first main electrode on the lower surface is connected to the first main terminal 720 of the case 7 via the first conductor pattern 321 of the wiring board 3C and the bonding wire 6A. The second main electrode on an upper surface of the semiconductor element is connected to the second conductor pattern 322 of the wiring board 3C by a bonding wire (for example, the bonding wire 6B), and the second conductor pattern 322 is connected to the second main terminal 730 of the case 7 by the bonding wire 6N. The control electrode on the upper surface of the semiconductor element is connected to the third conductor pattern 323 of the wiring board 3C by a bonding wire (for example, the bonding wire 6D), and the third conductor pattern 323 is connected to the control terminal 750 of the case 7 by the bonding wire 6F. The case 7 is provided with the discharge wiring board 10 used for discharge between the first main terminal 720 and the second main terminal 730.

FIG. 16 illustrates a half-bridge inverter circuit 16 including a first circuit 16A and a second circuit 16B, which are separate semiconductor devices 100. The first circuit 16A includes a first switching element 1604 and a first diode element 1606 corresponding to the upper arm 1611 illustrated in FIG. 5, and a collector-side terminal 1601A of the first switching element 1604 corresponds to the first main terminal 720 and an emitter-side terminal 1602A corresponds to the second main terminal 730. The second circuit 16B includes a second switching element 1605 and a second diode element 1607 corresponding to the lower arm 1612 illustrated in FIG. 5, and a collector-side terminal 1601B of the second switching element 1605 corresponds to the first main terminal 720 and an emitter-side terminal 1602B corresponds to the second main terminal 730. The emitter-side terminal 1602A of the first circuit 16A and the collector-side terminal 1601B of the second circuit 16B are electrically connected by, for example, a terminal plate that functions as the OUT terminal 1603 in the half-bridge inverter circuit 16 (may be referred to as a bus bar) or the like. At this time, the collector-side terminal 1601A in the first circuit 16A functions as the P terminal 1601 in the half-bridge inverter circuit 16, and the emitter-side terminal 1602B in the second circuit 16B functions as the N terminal 1602 in the half-bridge inverter circuit 16 (see FIG. 5).

In the half-bridge inverter circuit 16 formed using the semiconductor device 100 illustrated in FIG. 15, the discharge path 1620 may be formed in each of the first circuit 16A and the second circuit 16B formed by the separate semiconductor devices 100. The discharge path 1620 illustrated in FIG. 16 may use the discharge wiring board 10 (see FIGS. 3 and 4, and FIGS. 11 and 12), or may be a portion integrally formed with the first main terminal 720 and the second main terminal 730 (see FIGS. 13 and 14).

In addition, in the semiconductor devices 1 and 100 using the discharge wiring board 10 described above with reference to FIGS. 3 and 4, for example, the first conductor pattern 12 and the second conductor pattern 13 formed on the upper surface of the insulating substrate 11 may be connected to the first main terminal 720 and the second main terminal 730, respectively, via a high-resistance member.

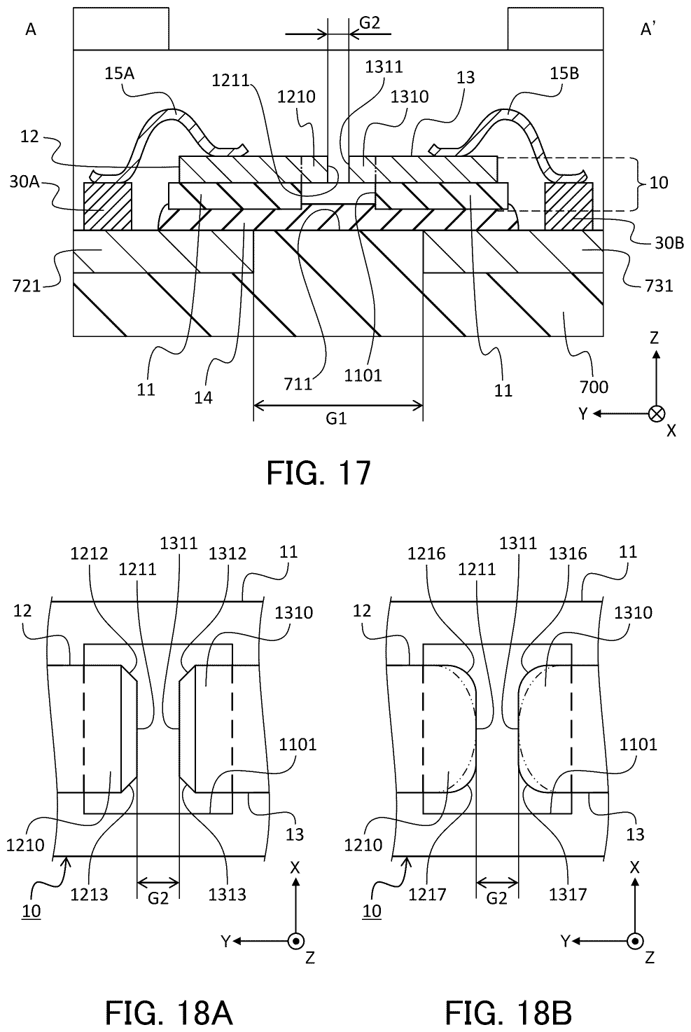

FIG. 17 is a cross-sectional view for explaining another example of a connection method of the discharge wiring board. The cross-sectional view in FIG. 17 corresponds to the cross section taken along line A-A′ in FIG. 3. The discharge wiring board 10 illustrated in FIG. 17 has the configuration described above with reference to FIGS. 3 and 4, and the first conductor pattern 12 and the second conductor pattern 13 are formed on the upper surface of the insulating substrate 11, and are adhered to the surface 711 of the case member 700 with the adhesive 14. The shapes of the discharge portion 1210 of the first conductor pattern 12 and the discharge portion 1310 of the second conductor pattern 13 are not limited to the rectangular parallelepiped, and may be the shapes illustrated in FIGS. 18A and 18B. In the discharge wiring board 10 illustrated in FIGS. 3 and 4, the end portion on the inner connection portion 721 side of the bonding wire 15A that connects the first conductor pattern 12 formed on the upper surface of the insulating substrate 11 and the inner connection portion 721 of the first main terminal 720 is directly connected to the upper surface of the inner connection portion 721. Similarly, the end portion on the inner connection portion 731 side of the bonding wire 15B that connects the second conductor pattern 13 and the inner connection portion 731 of the second main terminal 730 is directly connected to the upper surface of the inner connection portion 731.

On the other hand, in the connection method of the discharge wiring board 10 illustrated in FIG. 17, high-resistance members 30A and 30B are provided on the inner connection portion 721 of the first main terminal 720 and on the inner connection portion 731 of the second main terminal 730, respectively, one end of the bonding wire 15A is connected to the high-resistance member 30A, and one end of the bonding wire 15B is connected to the high-resistance member 30B. The high-resistance members 30A and 30B are formed of, for example, a material having a resistance of about 200 kΩ, another suitable insulating material, or the like. The shapes of the high-resistance members 30A and 30B are not limited to a specific shape.

By providing the high-resistance members 30A and 30B, for example, the impedance in the discharge path 1620 (see FIG. 5) increases, and thus surge energy can be effectively absorbed. Therefore, damage or the like of the semiconductor device due to the surge voltage can be made less likely to occur.

The embodiment of the semiconductor device 1 according to the present invention is not limited to the above embodiment, and various changes, substitutions, and modifications may be made without departing from the spirit of the technical idea. Further, when the technical idea can be realized in another manner by the progress of the technology or another derived technology, the technical idea may be carried out by using a method thereof. Therefore, the claims cover all embodiments that may be included within the scope of the technical idea.

For example, the switching elements of the semiconductor elements 4 of the semiconductor device 1 are not limited to the above-described IGBT element, and may include, for example, a power metal oxide semiconductor field effect transistor (MOSFET), a bipolar junction transistor (BJT), or the like. When the switching element is a MOSFET element, the main electrode on a lower surface side of the semiconductor elements 4 may be referred to as a drain electrode, and the main electrode on the upper surface side may be referred to as a source electrode. Furthermore, the diode elements of the semiconductor elements 4 may include, for example, a schottky barrier diode (SBD), a junction barrier schottky (JBS) diode, a merged PN schottky (MPS) diode, a PN diode, or the like. In addition, the control electrode provided on an upper surface of the semiconductor elements 4 may include a gate electrode and an auxiliary electrode. For example, the auxiliary electrode may be an auxiliary emitter electrode or an auxiliary source electrode electrically connected to the main electrode on the upper surface side and serving as a reference potential with respect to a gate potential. Furthermore, the auxiliary electrode may be a temperature sensing electrode that is electrically connected to a temperature sensing unit that may be included in an inverter device or the like including the semiconductor device 1 and measures temperatures of the semiconductor elements 4.

In addition, the half-bridge inverter circuit 16 in the semiconductor device 1 may include, for example, a semiconductor element having a switching element and a semiconductor element having a diode element. The inverter circuit formed in the semiconductor device 1 may be a full-bridge inverter circuit. The inverter circuit formed in the single semiconductor device 1 is not limited to the single-phase AC inverter circuit as described above with reference to FIG. 5, and may be a three-phase AC inverter circuit or the like.

The semiconductor devices 1 and 100 according to the above-described embodiment can be applied to, for example, industrial power conversion devices such as inverter devices or the like that drive motors of elevators, escalators, air conditioning systems of buildings, railway vehicles, or the like. Note that the applications of the semiconductor devices 1 and 100 are not limited to specific applications. In addition, the semiconductor device having the above-described discharge portion is not limited to the semiconductor device 1 having the inverter circuit (see FIG. 1) and the semiconductor device 100 (see FIG. 15) usable for the formation of the inverter circuit.

Feature points in the embodiment described above will be summarized below.

A semiconductor device according to the above-described embodiment includes: a circuit board including a wiring board and a semiconductor element disposed on a first surface of the wiring board; a case having a hollow portion housing the circuit board; and a first conductive terminal and a second conductive terminal attached to the case, each of the first conductive terminal and the second conductive terminal having an inner connection portion exposed toward the hollow portion of the case and an outer connection portion exposed in a direction away from the hollow portion, in which the first conductive terminal and the second conductive terminal each have a discharge portion facing each other across a second gap narrower than a first gap between the inner connection portions in the hollow portion of the case, and the discharge portion of the first conductive terminal and the discharge portion of the second conductive terminal protrude to a position away from other members and face each other via a gas.

In the semiconductor device according to the above-described embodiment, the first conductive terminal is electrically connected to a first terminal of a circuit formed on the circuit board, the second conductive terminal is electrically connected to a second terminal of the circuit, and a gap between the discharge portion of the first conductive terminal and the discharge portion of the second conductive terminal has a size such that discharge occurs when a potential difference between the first conductive terminal and the second conductive terminal becomes equal to or larger than a potential difference set based on an operating voltage of the circuit.

In the semiconductor device according to the above-described embodiment, an inverter circuit is formed on the circuit board, the first conductive terminal is connected to a first input end of the inverter circuit, and the second conductive terminal is connected to a second input end of the inverter circuit.

The semiconductor device according to the above-described embodiment further includes a discharge wiring board in which a first conductor pattern and a second conductor pattern are disposed on a first surface of an insulating substrate so as to face each other across the predetermined gap, in which the insulating substrate has an opening with the first surface open, the first conductor pattern and the second conductor pattern each have a discharge portion extending over the opening, protruding to a position away from other members, and facing each other across the predetermined gap via the gas, the discharge wiring board is attached to the case with a second surface of the insulating substrate opposite to the first surface facing the case in the hollow portion of the case, and the first conductor pattern is electrically connected to the first conductive terminal as the discharge portion of the first conductive terminal and the second conductor pattern is electrically connected to the second conductive terminal as the discharge portion of the second conductive terminal.

In the semiconductor device according to the above-described embodiment, the inner connection portion of the first conductive terminal and the inner connection portion of the second conductive terminal are disposed on a single surface facing the hollow portion in the case, and the discharge portion of the first conductive terminal and the discharge portion of the second conductive terminal face each other in an in-plane direction of the single surface.

The semiconductor device according to the above-described embodiment further includes a cooler disposed at a position facing a second surface of the wiring board opposite to the first surface and thermally connected to the wiring board.

The semiconductor device according to the above-described embodiment further includes a sealing material that seals the circuit board such that the discharge portion of the first conductive terminal and the discharge portion of the second conductive terminal protrude to the position away from the other members and face each other via the gas.

As described above, according to the present invention, it is possible to make the configuration of the discharge portion that performs discharge when an overvoltage exceeding an assumption of device design due to a lightning strike or the like is applied to the semiconductor device less likely to vary among individual devices, and thus it is possible to more reliably prevent a failure such as the breakdown of the semiconductor element inside the semiconductor device due to the overvoltage. Such a semiconductor device is particularly applied to industrial power conversion devices (inverter devices) of elevators, escalators, air conditioning equipment, railway vehicles, and the like that are operated by commercial power sources, thereby making it possible to avoid a failure or an emergency stop due to a lightning strike or the like.

What is claimed is:

1. A semiconductor device comprising:
a circuit board, including:
a wiring board, and
a semiconductor element disposed on a first surface of the wiring board;
a case having a hollow portion housing the circuit board; and
a first conductive terminal and a second conductive terminal attached to the case, wherein
each of the first conductive terminal and the second conductive terminal has an inner connection portion exposed to the hollow portion of the case, the inner connection portions having a first gap therebetween, and
each of the first conductive terminal and the second conductive terminal has a discharge portion, the discharge portions facing each other across a second gap and with a gas therebetween, the second gap being narrower than the first gap, and the discharge portion of the first conductive terminal and the discharge portion of the second conductive terminal protrude to a position away from other members.

2. The semiconductor device according to claim 1, wherein
the circuit board has a circuit formed thereon that has a first terminal and a second terminal,
the first conductive terminal is electrically connected to the first terminal, and the second conductive terminal is electrically connected to the second terminal, and
the second gap is sized to allow discharge to occur when a potential difference between the first conductive terminal and the second conductive terminal becomes equal to or larger than a potential difference that is set based on an operating voltage of the circuit.

3. The semiconductor device according to claim 1, wherein
the circuit board has an inverter circuit formed thereon that has a first input end and a second input end,
the first conductive terminal is connected to the first input end of the inverter circuit, and
the second conductive terminal is connected to the second input end of the inverter circuit.

4. The semiconductor device according to claim 1, further comprising a discharge wiring board, including:
an insulating substrate having a first surface and a second surface opposite to each other, and
a first conductor pattern and a second conductor pattern disposed on the first surface of the insulating substrate, so as to face each other across the second gap, wherein
the insulating substrate has an opening formed in the first surface thereof,
the first conductor pattern and the second conductor pattern each have a discharge end extending over the opening, the discharge ends facing each other across the second gap via the gas,
the discharge wiring board is attached to the case with the second surface of the insulating substrate facing the case in the hollow portion,
the first conductor pattern is electrically connected to the first conductive terminal and constitutes the discharge portion of the first conductive terminal, and
the second conductor pattern is electrically connected to the second conductive terminal and constitutes the discharge portion of the second conductive terminal.

5. The semiconductor device according to claim 1, wherein
the inner connection portion of the first conductive terminal and the inner connection portion of the second conductive terminal are disposed on a same surface of the case, and
the discharge portion of the first conductive terminal and the discharge portion of the second conductive terminal face each other in an in-plane direction of said same surface.

6. The semiconductor device according to claim 1, wherein
the wiring board further has a second surface opposite to the first surface, and
the semiconductor device further includes a cooler that is disposed at a position facing the second surface of the wiring board and that is thermally connected to the wiring board.

7. The semiconductor device according to claim 1, further comprising a sealing material that seals the circuit board in such a way as to allow the discharge portion of the first conductive terminal and the discharge portion of the second conductive terminal protrude to face each other via the gas.
